(19) United States
(12) Patent Application Publication
(10) Pub. No.: US 2011/0261849 A1
(43) Pub. Date: Oct. 27, 2011

(54) SEMICONDUCTOR LIGHT EMITTING ELEMENT AND METHOD OF MANUFACTURING THEREOF

(75) Inventors: Tatsuyuki Shinagawa, Tokyo (JP); Hirotatsu Ishii, Tokyo (JP); Hirokazu Sasaki, Tokyo (JP); Akihiko Kasukawa, Tokyo (JP)

(73) Assignee: FURUKAWA ELECTRIC CO., LTD., Tokyo (JP)

(21) Appl. No.: 13/038,951

(22) Filed: Mar. 2, 2011

(30) Foreign Application Priority Data
Mar. 4, 2010 (JP) 2010-048305
Feb. 25, 2011 (JP) 2011-039757

(51) Int. Cl. H01S 5/323; H01S 5/18; H01L 33/02

(52) U.S. Cl. 372/45.01; 257/43; 438/46; 257/103; 257/E33.013

(57) ABSTRACT

A semiconductor light emitting element comprising: a buffer layer that is grown by using a growth substrate including ZnO, the buffer layer being made by using an AlGaInN-based material including In and being configured so that the growth surface thereof has a nitrogen polar plane; and an active layer that is formed on the buffer layer, the active layer being made by using an AlGaInN-based material including In and being configured so that the growth surface thereof has a group-III polar plane.

### CROSS-REFERENCE TO RELATED APPLICATION

This application is based upon and claims the benefit of priority from the prior Japanese Patent Application No. 2010-048305, filed on Mar. 4, 2010 and the prior Japanese Patent Application No. 2011-039757, filed on Feb. 25, 2011; the entire contents of which are incorporated herein by reference.

### BACKGROUND OF THE INVENTION

1. Field of the Invention

The present invention relates to a semiconductor light emitting element and a method of manufacturing thereof.

2. Description of the Related Art

Conventionally, as a method for realizing an indium gallium nitride (InGaN) layer (including an indium nitride (InN) layer) that has an excellent crystal quality and is to be used for a semiconductor light emitting element or the like, a technique by which the InGaN layer is grown on a zinc oxide (ZnO) substrate at a temperature lower than 500° C. has been disclosed (see Japanese Patent Application Laid-open No. 2008-053640). By using this technique, it is possible to prevent interfacial reactions between the ZnO and the InGaN from occurring when the crystals are grown. Thus, it is considered that this technique makes it possible to obtain an InGaN layer that achieves lattice matching with the ZnO substrate and has an excellent crystal quality.

Further, as another method for realizing an InGaN layer that has an excellent crystal quality, a method has been disclosed by which an InGaN layer having a nitrogen polar surface is used (see Japanese Patent Application Laid-open No. 2004-140339). By using this method, it is possible to cause the crystals to grow at a higher growth temperature. Thus, it is considered that this method makes it possible to obtain an InGaN layer that has an excellent crystal quality.

### SUMMARY OF THE INVENTION

It is an object of the present invention to at least partially solve the problems in the conventional technology.

In accordance with one aspect of the present invention, a semiconductor light emitting element comprising: a buffer layer that is grown by using a growth substrate including ZnO, the buffer layer being made by using an AlGaInN-based material including In and being configured so that a growth surface thereof has a nitrogen polar plane; and an active layer that is formed on the buffer layer, the active layer being made by using an AlGaInN-based material including In and being configured so that a growth surface thereof has a group-III polar plane.

In accordance with another aspect of the present invention, a method of manufacturing a semiconductor light emitting element comprising: growing a buffer layer on a growth substrate including ZnO, the buffer layer being made by using an AlGaInN-based material including In and being configured so that a growth surface thereof has a nitrogen polar plane; and growing an active layer on the buffer layer, the active layer being made by using an AlGaInN-based material including In and being configured so that a growth surface thereof has a group-III polar plane.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a schematic cross-sectional view of a semiconductor light emitting element according to a first embodiment of the present invention;

FIG. 2 is a chart for explaining a relationship between a lattice constant (a) in the a-axis direction of a crystal lattice of an AlGaInN-based material and a band gap energy;

FIG. 3 is a chart for explaining a relationship between the lattice constant (a) of the AlGaInN-based material and a refractive index;

FIG. 4 is a schematic cross-sectional view of a semiconductor light emitting element of Comparison Example 1;

FIG. 5 is a schematic cross-sectional view of a semiconductor light emitting element of Example 1;

FIG. 6 is an image of the InGaN layers including light emitting layer and the active layer of the semiconductor light emitting element of Example 1 obtained by using the ABF-STEM method;

FIG. 7 is an image of the buffer layer of the semiconductor light emitting element of Example 1 obtained by using the ABF-STEM method;

FIG. 8 is a graph of photoluminescence spectrum of the semiconductor light emitting element of Comparison Example 1;

FIG. 9 is a graph of a photoluminescence spectrum of the semiconductor light emitting element of Embodiment Example 1; and

FIG. 10 is a schematic cross-sectional view of a semiconductor light emitting element according to a second embodiment of the present invention.

### DETAILED DESCRIPTION OF THE PREFERRED EMBODIMENTS

In the following sections, exemplary embodiments of a semiconductor light emitting element and a method of manufacturing thereof according to the present invention will be explained in detail, with reference to the accompanying drawings. The present invention is not limited to these exemplary embodiments. It is possible to apply various modifications to the exemplary embodiments without departing from the gist of the present invention.

When the inventors of the present invention caused an InGaN layer to grow on a ZnO substrate at a temperature that is lower than 500° C. and evaluated the photoluminescence characteristics thereof, there were some situations where the fill width at half maximum of the photoluminescence spectrum was large and where it was not possible to obtain a light emission having a sufficient level of intensity. In contrast, according to the exemplary embodiments described below, it is possible to realize a semiconductor light emitting element that has excellent photoluminescence characteristics.

First, a semiconductor light emitting element according to a first embodiment of the present invention will be explained. The semiconductor light emitting element according to the first embodiment is a laser element that is of an edge emitting type and has a laser oscillation wavelength of 530 nanometers.

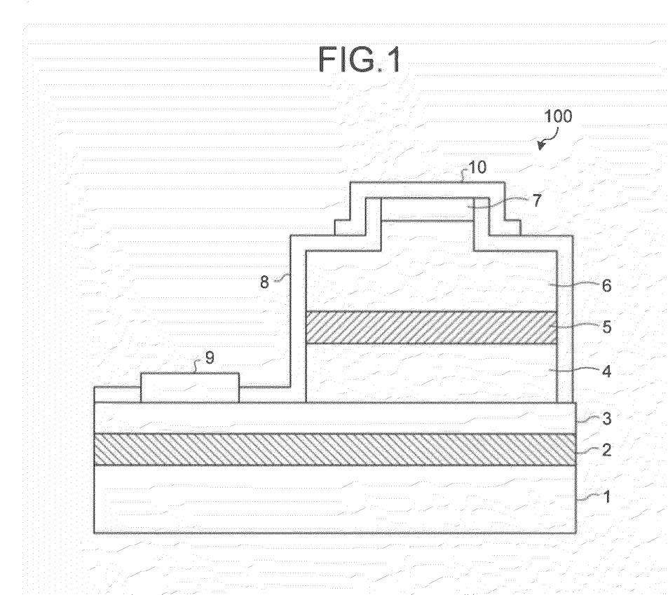

FIG. 1 is a schematic cross-sectional view of the semiconductor light emitting element according to the first embodiment. As shown in FIG. 1, a semiconductor light emitting element 100 according to the first embodiment includes a substrate 1 and the following that are formed on the substrate 1: a buffer layer 2; a lower contact layer 3; a lower cladding layer 4; an active layer 5; an upper cladding layer 6; an upper contact layer 7; a passivation film 8; a lower electrode 9; and an upper electrode 10. The passivation film 8 is electrically insulative and covers a surface of the semiconductor light emitting element 100 as a protection film. Further, the passivation film 8 has openings above the surface of the upper contact layer 7 and in part of the area that is a surface area of the lower contact layer 3 but is other than the area where the lower cladding layer 4 is formed. The lower electrode 9 and the upper electrode 10 are each in ohmic contact with a corresponding one of the lower contact layer 3 and the upper contact layer 7, via the corresponding one of the openings.

Further, the semiconductor light emitting element 100 has facets that have been formed by a cleaving process or the like and that extend parallel to each other, on the far side and on the near side of the drawing page. Of these facets, the light-exiting-side facet has a low-reflectivity film formed thereon that has, for example, a reflectivity of 10% or lower, whereas the light-reflecting-side facet has a high-reflectivity film formed thereon that has, for example, a reflectivity of 90% or higher. The high-reflectivity film and the low-reflectivity film together structure an optical resonator while the active layer 5 is interposed therebetween.

In the following sections, the constituent elements will be explained more specifically. First, the substrate 1 that serves as a supporting substrate as well as a growth substrate is made by using a single crystal of ZnO, which is a group II-VI compound semiconductor having a Wurtzite crystal structure. The main surface of the substrate 1 corresponds to the c-plane of the crystal lattice. In this situation, the “main surface of the substrate” refers to the main surface on which the semiconductor layers are grown. By configuring the main surface of the substrate 1 serving as the growth substrate so as to correspond to the c-plane, it is possible to substantially achieve lattice matching between the semiconductor layers grown on the substrate 1 and the substrate 1. Further, it is preferable if the substrate 1 is a vicinal substrate of which the main surface is slightly inclined with respect to the c plane toward the direction of the m-axis at an off-angle of approximately ±1 degree, because it is easy to cause a planar semiconductor layer to grow on the main surface.

Also, it is preferable if, in particular, the main surface of the substrate 1 corresponds to a −c(000_{—}1) plane, which is an oxygen polar surface. It is more preferable when the main surface of the substrate 1 is an oxygen polar surface, because it is easier to cause a planar semiconductor layer to grow on the main surface.

Next, compositions of the semiconductor layers that are grown on the substrate 1, namely, from the buffer layer 2 through the upper contact layer 7, will be explained more specifically. Each of the semiconductor layers is made by using InGaN, which is an AlGaInN-based material of a group III-V compound semiconductor having a Wurtzite crystal structure. The composition ratio is set for each of the semiconductor layers.

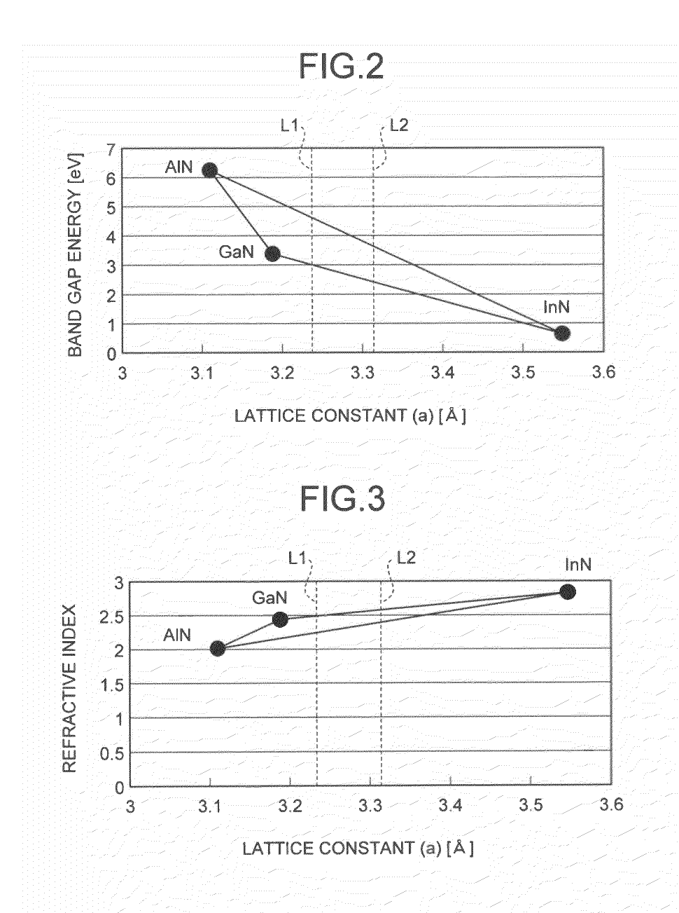

FIG. 2 is a chart for explaining a relationship between a lattice constant (a) in the a-axis direction of a crystal lattice of the AlGaInN-based material and a band gap energy. FIG. 3 is a chart for explaining a relationship between the lattice constant (a) of the AlGaInN-based material and a refractive index at a wavelength of 530 nanometers. In the following sections, a lattice constant (a) denotes a lattice constant in the a-axis direction.

In FIGS. 2 and 3, the filled circles are data points showing relationships between the lattice constants (a) of AlN, GaN, and InN and the band gap energies or the refractive indices. Further, the lattice constant (a) of gallium nitride (GaN) is 3.189 angstroms (Å) (1 Å is equal to 0.1 nanometer), whereas the lattice constant (a) of indium nitride (InN) is 3.548 angstroms, and the lattice constant (a) of aluminum nitride (AlN) is 3.112 angstroms. When an AlGaInN-based material is being used, the data points should be present either on a side (indicated with a solid line) of, or on the inside of, the triangle obtained by connecting the filled circles to one another, depending on the composition ratio of the elements of the composition. Further, the line L1 indicates the position corresponding to 3.2407 angstroms, which is the lattice constant (a) of ZnO included in the substrate 1.

The active layer 5 includes InGaN in which the proportion of the In is approximately 30%. The active layer 5 has the lattice constant (a) that is indicated by the line L2 in FIGS. 2 and 3. Accordingly, the band gap energy of the active layer 5 is 2.34 eV, which corresponds to the band gap energy positioned at the intersection of the solid line connecting together the data points of GaN and InN in FIG. 2 and the line L2. The light wavelength obtained by converting the band gap energy of the active layer 5 is 530 nanometers, which corresponds to the laser oscillation wavelength of the semiconductor light emitting element 100. Further, the refractive index of the active layer 5 corresponds to the refractive index positioned at the intersection of the solid line connecting together the two points of GaN and InN in FIG. 3 and the line L2.

Furthermore, as indicated by the lines L1 and L2 in FIGS. 2 and 3, the lattice constant (a) of the substrate 1 and the lattice constant (a) of the active layer 5 have the values that fall between the lattice constant (a) of GaN and the lattice constant (a) of InN and that are closer to each other.

The buffer layer 2, the lower contact layer 3, the lower cladding layer 4, the upper cladding layer 6, and the upper contact layer 7 substantially achieve lattice matching with the substrate 1. The band gap energies and the refractive indices of these layers correspond to the values at the intersections of the solid line connecting together the two data points of GaN and InN and the line L2 in FIGS. 2 and 3, respectively. Accordingly, the band gap energy of each of these semiconductor layers is higher than the band gap energy of the active layer 5. Also, the refractive index of each of these semiconductor layers is lower than the refractive index of the active layer 5. As a result, by using these semiconductor layers, it is possible to confine light and carriers in the active layer 5.

Further, the lower contact layer 3 and the lower cladding layer 4 each have the n-type conductivity. In contrast, the upper cladding layer 6 and the upper contact layer 7 each have the p-type conductivity.

Further, a part or all of the growth surface of the buffer layer 2 is a nitrogen polar plane. In contrast, as for the lower contact layer 3, the lower cladding layer 4, the active layer 5, the upper cladding layer 6, and the upper contact layer 7 that are formed on the buffer layer 2, all of each of the growth surfaces thereof is a group-III polar plane.

The passivation film 8 is made by using dielectric material such as SiO₂ or ZrO₂. Further, the lower electrode 9 has, for example, a Ti/Al structure or a Ti/Pt/Au structure. The upper electrode 10 has, for example, an Ni/Au structure or a Pd/Pt/Au structure.

Next, an operation performed by the semiconductor light emitting element 100 will be explained. When a voltage is applied between the upper electrode 10 and the lower electrode 9, and also, electric current is injected into the active layer 5, the active layer 5 generates light including light in the wavelength of 530 nanometers. The generated light is optically amplified by the active layer 5 while being guided through the active layer 5, which is serving as a waveguide. Due to an action of the optical resonator structured by the low-reflectivity film and the high-reflectivity film, the generated light causes a laser oscillation at the wavelength of 530 nanometers. Because the laser beam is emitted through the facet on the low-reflectivity-film side, the semiconductor light emitting element 100 is a semiconductor laser element of an edge emitting type.

As described above, the semiconductor light emitting element 100 is configured so that the growth surface of the buffer layer 2 has a nitrogen polar plane, whereas each of the growth surfaces of the lower contact layer 3, the lower cladding layer 4, the active layer 5, the upper cladding layer 6, and the upper contact layer 7 that are formed on the buffer layer 2 has a group-III polar plane. As a result, the semiconductor light emitting element 100 achieves an advantageous effect where the active layer 5 has a sufficient level of photoluminescence intensity and a photoluminescence spectrum with a small full with at half maximum. Thus, the semiconductor light emitting element 100 is a laser element having extremely excellent photoluminescence characteristics.

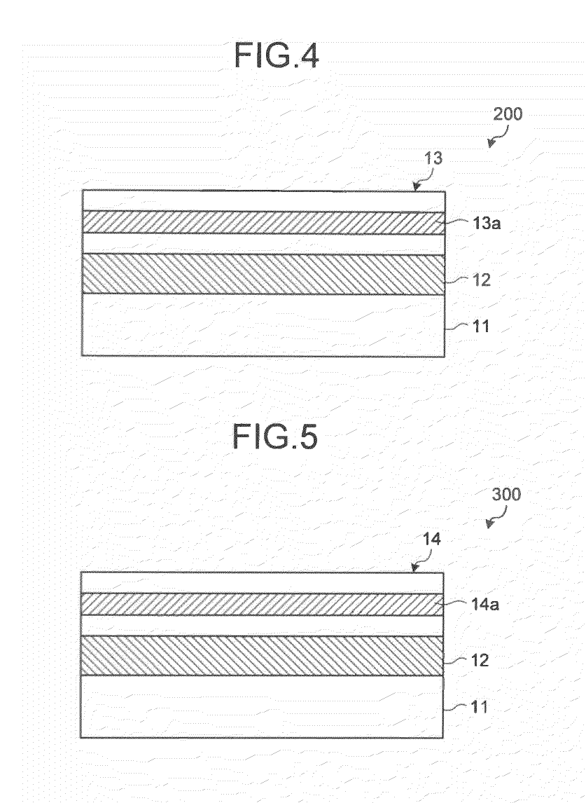

In the following sections, advantageous effects achieved by the first embodiment will be explained by using Example and Comparison Example. First, a semiconductor light emitting element 200 of which a schematic cross-sectional view is shown in FIG. 4 was manufactured as Comparison Example 1. The semiconductor light emitting element 200 was manufactured by sequentially causing a buffer layer 12 including InGaN and a light emitting layer 13 including InGaN and including an active layer 13a that has a single quantum well structure to grow on a substrate 11 of which the main surface corresponds to the c-plane and that including ZnO, by performing a crystal growing process at a low temperature that is lower than 500° C. as disclosed in Japanese Patent Application Laid-open No. 2008-053640. The proportion of the In contained in the active layer 13a was configured so that the center wavelength of the photoluminescence is 530 nanometers. As the state of the surface was examined during and after the manufacture of the semiconductor light emitting element of Comparison Example 1 by using a Co-Axial Impact-Collision Ion Scattering Spectroscopy (CAICISS) method, each of the growth surfaces of the buffer layer 12 and the light emitting layer 13 had a nitrogen polar plane.

Next, as Example 1, a semiconductor light emitting element 300 of which a schematic cross-sectional view is shown in FIG. 5 was manufactured. The semiconductor light emitting element 300 was manufactured by causing the buffer layer 12 including InGaN to grow on the substrate 11 of which the main surface corresponds to the c-plane and that includes ZnO, by performing a crystal growing process at a low temperature as disclosed in Japanese Patent Application Laid-open No. 2008-053640, and subsequently, causing a light emitting layer 14 to grow at a high temperature that is equal to or higher than 500° C., the light emitting layer 14 including InGaN and including an active layer 14a that has a single quantum well structure. The proportion of the In contained in the active layer 14a was configured so that the center wavelength of the photoluminescence is 530 nanometers. As the state of the surface was examined during and after the manufacture of the semiconductor light emitting element of Example 1 by using the CAICISS method, the growth surface of the buffer layer 12 had a nitrogen polar plane, whereas the growth surface of the light emitting layer 14 had a group-III polar plane.

To investigate the growth surface of the buffer layer 12 and the light emitting layer 14 in more detail, the semiconductor light emitting element 300 of Example 1 is observed by using an ABF-STEM (Annular Bright Field-Scanning Transmission Electron Microscopy) method. The ABF-STEM method is a kind of methods using TEM. The ABF-STEM method can identify a position of a nitrogen atom which is difficult to observe by using an HAADF-STEM (High Angle Annular Dark Field-Scanning Transmission Electron microscopy) method.

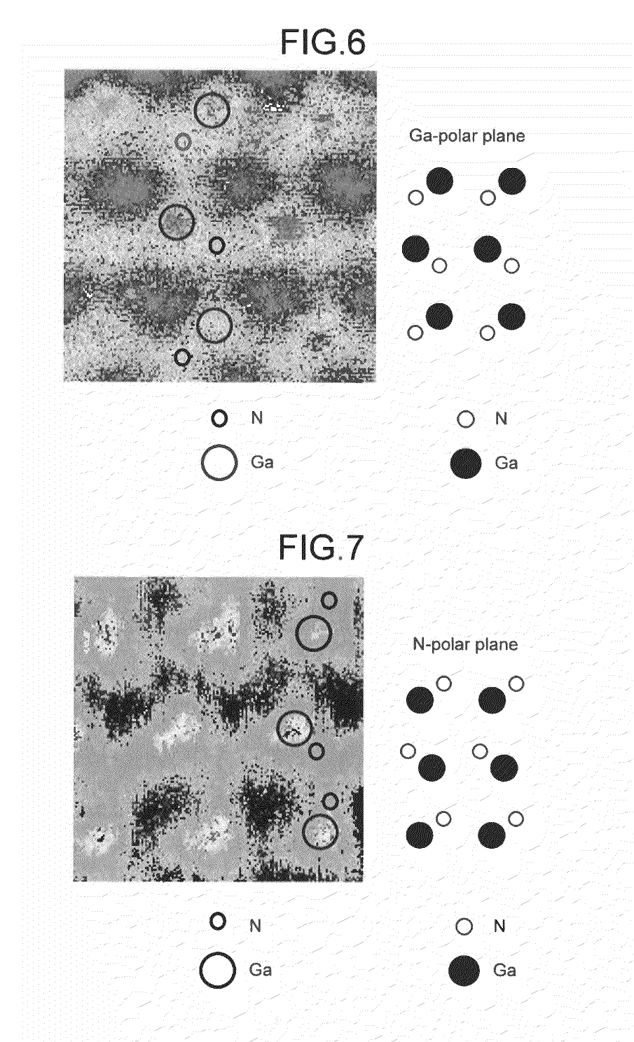

FIG. 6 is an image of the InGaN layers including light emitting layer 14 and the active layer 14a of the semiconductor light emitting element 300 of Example 1 obtained by using the ABF-STEM method. Open circles indicate positions of Ga or nitrogen atoms. Schematic atomic arrangement of a Ga polar plane is also shown in FIG. 6. As shown in FIG. 6, it is confirmed that the surface of the InGaN layers including light emitting layer 14 and the active layer 14a has a group-III polar plane.

FIG. 7 is an image of the buffer layer 12 composed of InGaN of the semiconductor light emitting element 300 of Example 1 obtained by using the ABF-STEM method. Open circles indicate positions of Ga or nitrogen atoms. Schematic atomic arrangement of a nitrogen polar plane is also shown in FIG. 7. As shown in FIG. 7, it is confirmed that the surface of the buffer layer 12 has a nitrogen polar plane in large part of the surface while having another polar plane in a part. In such a manner, the ABF-STEM method can identify a surface polarization of the manufactured semiconductor light emitting element.

Compared to FIG. 7, the positions of the atoms are clearly observed in the ABF-STEM image in FIG. 6. It indicates that a crystal quality of an active layer can be more improved by introducing a buffer layer between the active layer and a substrate which includes the different material from that of the active layer compared to the case where an InGaN active layer is grown directly on a ZnO substrate.

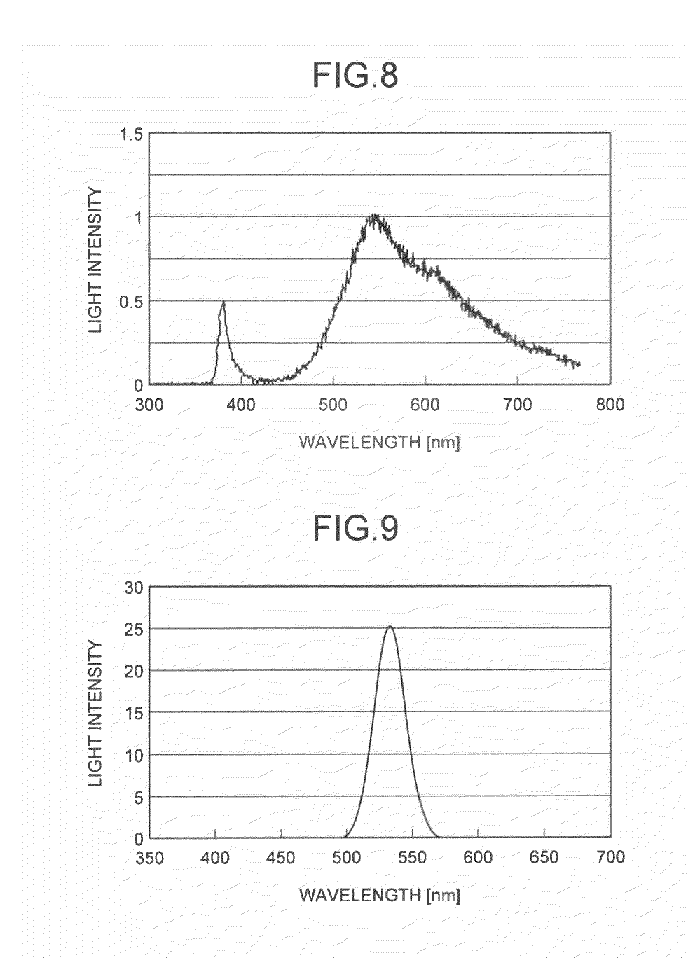

Next, excitation light was radiated on the semiconductor light emitting elements of Example 1 and Comparison Example 1 so as to measure the photoluminescence characteristics thereof. FIG. 8 is a graph of a photoluminescence spectrum of the semiconductor light emitting element of Comparison Example 1. The light intensity expressed on the vertical axis is based on relative values. Further, the photoluminescence peak at the wavelength of 380 nanometers is of a photoluminescence of ZnO included in the substrate.

As shown in FIG. 8, a broad photoluminescence spectrum having a low intensity was observed from the semiconductor light emitting element of Comparison Example 1. The peak wavelength of the photoluminescence spectrum was 540 nanometers and was different from the wavelength expected from the composition of the active layer. Thus, it is considered that the photoluminescence is from impurities and intrinsic defects within the crystals.

In contrast, FIG. 9 is a graph of a photoluminescence spectrum of the semiconductor light emitting element of Example 1. The light intensity indicated on the vertical axis is based on relative values and is expressed so that the scale thereof matches the vertical axis in FIG. 8. As shown in FIG. 9, a photoluminescence spectrum having a peak intensity that is approximately 25 times larger than the peak intensity of Comparison Example 1 was observed from the semiconductor light emitting element of Embodiment Example 1. The peak wavelength of the photoluminescence spectrum was approximately 530 nanometers, which is a wavelength expected from the composition of the active layer. Also, the spectral width at the peak of the photoluminescence spectrum was sufficiently small. Thus, it is considered that the crystal quality of the active layer is excellent.

In other words, as observed in Example 1, it has been confirmed that it is possible to realize a semiconductor light emitting element that has a high photoluminescence intensity and has extremely excellent photoluminescence characteristics, with the semiconductor light emitting element including: the buffer layer that has been grown on the substrate including ZnO and that includes InGaN of which the growth surface has the nitrogen polar plane; and the active layer that has been grown on the buffer layer and that includes InGaN of which the growth surface has the group-III polar plane.

As explained above, the semiconductor light emitting element 100 according to the first embodiment achieves an advantageous effect where the active layer 5 has a sufficient level of photoluminescence intensity. Thus, the semiconductor light emitting element 100 is a laser element that has extremely excellent photoluminescence characteristics.

As additional information, in the case where the active layer is configured with InGaN in which the proportion of the In is large, for the purpose of realizing a laser oscillation wavelength that is longer than blue (i.e., approximately 480 nanometers or longer), in particular, a wavelength in a range from blue to green (i.e., approximately 480 nanometers to 550 nanometers), problems as described below are anticipated: there is a possibility that the composition of the In contained in the active layer may become non-uniform due to a phase separation and that the photoluminescence efficiency may become lower. Also, when InGaN is used, a piezoelectric field is generated inside the crystal due to the crystal structure. In the case where the proportion of the In is large, because the piezoelectric field is larger, there is a possibility that the probability of recombination to cause photoluminescence becomes lower and thus the efficiency of photoluminescence may become lower. In addition, another problem arises where, when the piezoelectric field is larger, the light-emission wavelength of the active layer shifts when electric current is injected.

In contrast, the semiconductor light emitting element 100 according to the first embodiment is configured so that the buffer layer 2, the lower contact layer 3, and the lower cladding layer 4, as well as the upper cladding layer 6 and the upper contact layer 7 achieve lattice matching with the substrate 1 and so that the lattice constants thereof have values that are close to the lattice constant of the active layer 5. As a result, because the impact of strains on the active layer 5 is significantly reduced, it is possible to strictly inhibit the phase separation and the enlargement of the piezoelectric field described above, and also, it is possible to strictly inhibit occurrence of threading dislocations and cracks. Consequently, the active layer 5 has higher quality, so that the semiconductor light emitting element 100 has better optical characteristics and higher reliability.

Next, a method of manufacturing the semiconductor light emitting element 100 according to the first embodiment will be explained.

Growth of the Semiconductor Layers

First, the substrate 1 made by using a ZnO single crystal is prepared. As for substrates that are made by using a ZnO single crystal, substrates having a diameter as large as 3 inches (i.e., 76.2 millimeters) are available, which are appropriate for a mass production of the elements. Also, a substrate that includes ZnO is preferable to a sapphire substrate because the substrate including ZnO has a higher heat conductivity. Further, although the main surface of the substrate 1 corresponds to the c-plane, it is preferable if the main surface corresponds to a −c(000_{—}1) plane, which is an oxygen polar plane. Also, it is more preferable that the substrate 1 is a vicinal substrate. In the following sections, it is assumed that the main surface of the substrate 1 corresponds to a −c(000_{—}1) plane.

Step 1

At the beginning, a surface flattening process is performed on the substrate 1. First, a Chemical Mechanical Polishing (CMP) process is performed on the substrate 1. After that, as a part of the surface flattening process, a heat treatment process is performed in the atmosphere so as to form a step-terrace structure on the main surface of the substrate 1. It is desirable to perform the surface flattening process while the substrate 1 is interposed between flat plates made of an inorganic material such as zirconia oxide or zinc oxide. Also, it is desirable to configure the conditions under which the heat treatment process is performed so that the temperature is in the range of 1000° C. to 1300° C., while the duration is 1 hour to 5 hours. After that, the substrate 1 is introduced into a growth chamber.

Step 2

Subsequently, in the growth chamber, a thermal cleaning process is performed on the substrate 1, either at the atmospheric pressure or at a reduced pressure. More specifically, the substrate 1 is heated at a temperature in the range of 700° C. to 750° C. for one minute to ten minutes so as to eliminate organic substances and the like. As a result of the thermal cleaning process, the substrate 1 is cleaned and the surface thereof is restructured. Thus, a streak pattern can be observed by using a Reflection High Energy Electron Diffraction (RHEED) testing method.

After that, the nitride semiconductor layers from the buffer layer 2 through the upper contact layer 7 are epitaxially grown on the substrate 1 serving as the growth substrate, by using a nitrogen Radio Frequency (RF) radical source Molecular Beam Epitaxy (MBE) method where an RF radical cell that is configured so as to supply nitrogen (which is a raw material for group V) as nitrogen radicals is used.

Step 3

First, by supplying appropriate amounts of indium (In) and gallium (Ga), which are group III elements, as well as the nitrogen radicals simultaneously to the surface of the substrate 1 at a temperature that is lower than 500° C. and is for example, equal to or higher than 200° C., InGaN crystals of which the growth surfaces have nitrogen polar plane are grown on the substrate 1 with a thickness of approximately 30 nanometers, so as to form the buffer layer 2. The reason why the InGaN crystals are grown at a low temperature in this manner is that the interfacial reactions between the ZnO included in the substrate 1 and the InGaN should be inhibited. Also, it is preferable to configure the growth temperature so as to be 250° C. or higher because it is possible to achieve a better crystal quality. Also, it is preferable to supply the nitrogen radicals at the beginning and to subsequently supply the group III elements because it is possible to achieve a better crystal quality.

It is possible to supply group III elements of the Ga and the In, as well as aluminum (Al) which is not used at the present step, by using a Knudsen cell. The supplied amounts of the group III elements and the nitrogen radicals are adjusted as appropriate according to the growth temperature, in such a manner that the ratio between the group III elements and the nitrogen radicals is close to 1:1, and also, in such a manner that a desired lattice-constant condition is satisfied. Further, in that situation, it is preferable to configure the supply condition in such a manner that the ratio of the nitrogen radicals to the group III elements is higher than 1:1 because it is possible to achieve a better crystal quality. Further, it is even more preferable to configure the supply condition in such a manner that the nitrogen radicals are supplied at the beginning, and subsequently, the group III elements are supplied, and also, in such a manner that the ratio of the nitrogen radicals to the group III elements is higher than 1:1 because it is possible to achieve an even better crystal quality.

Step 4

Subsequently, the supply of the In, the Ga, and the nitrogen radicals is temporarily stopped, and the growth temperature is set to a temperature that is higher than 500° C. and is for example, equal to or lower than 650° C., and the supply cells for the raw materials are configured so as to have desired cell temperatures. After that, by supplying In, Ga, and nitrogen radicals simultaneously, the lower contact layer 3 and the lower cladding layer 4 of which the growth surfaces each have a group-III polar plane are sequentially grown. By setting the growth temperature to the high temperature and supplying the desired amounts of In, Ga, and nitrogen radicals in this manner, it is possible to configure the polarities of the growth surfaces so as to obtain the group-III polar plane. In this situation, it is preferable to supply the group III elements at the beginning, and to subsequently supply the nitrogen radicals because it is possible to achieve a better crystal quality. Also, it is preferable to configure the supply condition in such a manner that the ratio of the group III elements to the nitrogen radicals is higher than 1:1 because it is possible to achieve a better crystal quality. Further, it is even more preferable to configure the supply condition in such a manner that the group III elements are supplied at the beginning, and subsequently, the nitrogen radicals are supplied, and also, in such a manner that the ratio of the group III elements to the nitrogen radicals is higher than 1:1 because it is possible to achieve an even better crystal quality. It should also be noted that, during the growth process, by doping the lower contact layer 3 and the lower cladding layer 4 with, for example, an appropriate amount of silicon (Si), which is an n-type dopant, it is possible to configure the lower contact layer 3 and the lower cladding layer 4 so as to have the n-type conductivity. As explained here, according to the first embodiment, the lower contact layer 3 and the lower cladding layer 4 are each configured with indium gallium nitride [InₓGa₁₋ₓN (0<x<1)].

Step 5

Subsequently, by keeping the growth temperature at a temperature that is higher than 500° C. and is for example, equal to or lower than 650° C. and changing the settings of the cell temperatures so as to achieve an appropriate In/Ga ratio and an appropriate V/III ratio (or, alternatively, by replacing the cells with another In cell and another Ga cell that have been set to appropriate temperatures in advance), and also, by simultaneously supplying In, Ga, and nitrogen radicals, the active layer 5 that includes InGaN having an In proportion corresponding to a desired photoluminescence wavelength and of which the growth surface has a group-III polar plane is grown. Like at Step 4, in this situation also, it is preferable to supply the group III elements at the beginning, and to subsequently supply the nitrogen radicals because it is possible to achieve a better crystal quality. Also, it is preferable to configure the supply condition in such a manner that the ratio of the group III elements to the nitrogen radicals is higher than 1:1, because it is possible to achieve a better crystal quality. Further, it is even more preferable to configure the supply condition in such a manner that the group III elements are supplied at the beginning, and subsequently, the nitrogen radicals are supplied, and also, in such a manner that the ratio of the group III elements to the nitrogen radicals is higher than 1:1 because it is possible to achieve an even better crystal quality. As described here, when the crystal quality of the active layer 5 is excellent, the light-emission characteristics thereof is also excellent. In addition, when the crystal quality of the buffer layer 2, the lower contact layer 3, and the lower cladding layer 4 that are formed beneath the active layer 5 is excellent, the crystal quality of the active layer 5 formed above those layers is also excellent accordingly. As a result, it is possible to achieve even better light-emission characteristics.

Step 6

After that, by keeping the growth temperature at a temperature that is higher than 500° C. and is for example, equal to or lower than 650° C. and changing the settings of the cell temperatures so as to achieve an appropriate In/Ga ratio and an appropriate V/III ratio (or, alternatively, by replacing the cells with another In cell and another Ga cell that have been set to appropriate temperatures in advance), and also, by simultaneously supplying In, Ga, and nitrogen radicals, the upper cladding layer 6 and the upper contact layer 7 of which the growth surfaces each have a group-III polar plane are grown. Like at Step 4, in this situation also, it is preferable to supply the group III elements at the beginning, and to subsequently supply the nitrogen radicals because it is possible to achieve a better crystal quality. Also, it is preferable to configure the supply condition in such a manner that the ratio of the group III elements to the nitrogen radicals is higher than 1:1 because it is possible to achieve a better crystal quality. Further, it is even more preferable to configure the supply condition in such a manner that the group III elements are supplied at the beginning, and subsequently, the nitrogen radicals are supplied, and also, in such a manner that the ratio of the group III elements to the nitrogen radicals is higher than 1:1 because it is possible to achieve an even better crystal quality. It should also be noted that, during the growth process, by doping the upper cladding layer 6 and the upper contact layer 7 with, for example, an appropriate amount of magnesium (Mg), which is a p-type dopant, it is possible to configure the upper cladding layer 6 and the upper contact layer 7 so as to have the p-type conductivity. It is also acceptable to use beryllium (Be) as the p-type dopant. Also, it is acceptable to perform a co-doping process by using magnesium (Mg) and silicon (Si), as a p-type co-doping process.

After the epitaxial growth steps described above have been performed, by taking the epitaxial wafer out of the growth chamber and applying a heat treatment thereto at a high temperature so as to activate the Mg, it is possible to configure the layers doped with the Mg so as to have the p-type conductivity.

At the steps described above, the nitrogen plasma condition may be configured so that, for example, the plasma electric power is in the range of 200 watts to 500 watts, whereas the nitrogen gas flow rate is in the range of 1.0 standard cc/min (sccm) to 5.0 sccm.

As a result of Steps 1 through 6 described above, an epitaxial wafer to be used for the semiconductor light emitting element 100 according to the first embodiment has been manufactured.

Formation of a Laser Diode Structure

Next, a procedure for forming a laser diode structure of the semiconductor light emitting element 100 by using the epitaxial wafer that has been manufactured as described above will be explained.

First, the layers from the lower cladding layer 4 through the upper contact layer 7 are formed so as to have a ridge structure as shown in FIG. 1, by using a photolithography technique and a dry etching technique.

After that, the passivation film 8 is formed. The passivation film 8 is formed by, for example, depositing SiO₂ or ZrO₂ while using a Plasma Chemical Vapor Deposition (PCVD) method.

Next, the upper electrode 10 is formed. To form the upper electrode 10, an electrode pattern is formed first by performing a photolithography process and, after the passivation film 8 over the upper contact layer 7 has been removed, an electrode metal having an Ni/Au structure or a Pd/Pt/Au structure is deposited by using a Resistance Heating (RH) evaporation method, an Electron Beam (EB) deposition method, or a sputter deposition method, and then a sintering process is performed. The upper electrode 10 that has been formed in this manner is in ohmic contact with the upper contact layer 7, which has the p-type conductivity.

Subsequently, the lower electrode 9 is formed. To form the lower electrode 9, an electrode pattern is formed first by performing a photolithography process and, after the passivation film 8 over the lower contact layer 3 has been removed, an electrode metal having a Ti/Al structure or a Ti/Pt/Au structure is deposited by using a resistance heating evaporation method, an electron beam deposition method, or a sputter deposition method, and then a sintering process is performed. The lower electrode 9 that has been formed in this manner is in ohmic contact with the lower contact layer 3, which has the n-type conductivity.

After that, the facets of the optical resonator are formed by performing a cleaving process. In this situation, the cleaved surfaces correspond to the m-plane. Further, the low-reflectivity film and the high-reflectivity film are formed on the light-exiting-side facet and the light-reflecting-side facet, respectively, which are the facets of the optical resonator that have been formed. After that, the element is separated by performing a dicing process. As a result, the semiconductor light emitting element 100 according to the first embodiment, which is a laser element of an edge emitting type, has thus been completed.

Next, a semiconductor light emitting element according to a second embodiment of the present invention will be explained. The semiconductor light emitting element according to the second embodiment is a surface-emitting laser element that has a laser oscillation wavelength of 530 nanometers.

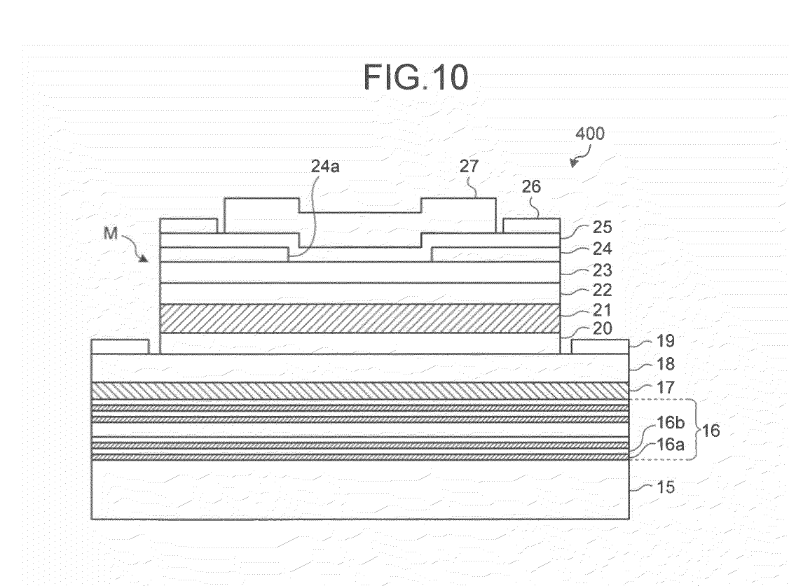

FIG. 10 is a schematic cross-sectional view of a semiconductor light emitting element 400 according to the second embodiment. As shown in FIG. 10, the semiconductor light emitting element 400 includes a substrate 15 and the following that are formed on the substrate 15: a lower Distributed Bragg Reflector (DBR) mirror 16 that functions as a lower multi-layer reflective mirror; a buffer layer 17; a lower contact layer 18; a lower electrode 19; a lower cladding layer 20; an active layer 21; an upper cladding layer 22; an upper contact layer 23; a current confinement layer 24; a transparent electrically-conductive film 25; an upper electrode 26; and an upper DBR mirror 27 that functions as an upper multi-layer reflective mirror. Of these constituent elements, the layered structure from the lower cladding layer 20 through the upper contact layer 23 is formed as a metapost M that is shaped in the form of a column by performing an etching process or the like. Further, the lower DBR mirror 16 and the upper DBR mirror 27 together structure an optical resonator while the active layer 21 is interposed therebetween.

In the following sections, the constituent elements will be explained more specifically. First, like the semiconductor light emitting element 100 according to the first embodiment, the substrate 15 includes ZnO and the main surface thereof corresponds to the c-plane. In particular, it is preferable that the main surface of the substrate 15 corresponds to a −c(000_{—}1) plane, which is an oxygen polar plane. It is more preferable that the substrate 15 is a vicinal substrate.

The lower DBR mirror 16 has a structure in which low-refractive-index layers 16a that are made by using MgBeO, which is a ZnMgBeCdO-based material and high-refractive-index layers 16b that includes ZnO are alternately laminated. The thickness of each of the low-refractive-index layers 16a and the high-refractive-index layers 16b is equal to λ/4n (λ: the laser oscillation wavelength; n: the refractive index) and is configured in such a manner that the reflection center wavelength of the lower DBR mirror 16 becomes equal to the laser oscillation wavelength. The materials used for obtaining the low-refractive-index layers 16a and the high-refractive-index layers 16b do not necessarily have to be those described above; it is acceptable to select, as necessary, any ZnMgBeCdO-based material.

Further, each of the semiconductor layers from the buffer layer 17 through the upper contact layer 23 includes InGaN, and the composition ratio thereof is set for each of the semiconductor layers.

The active layer 21 includes InGaN in which the proportion of the In is approximately 30%. The active layer 21 has the lattice constant (a) that is indicated by the line L2 in FIGS. 2 and 3. The light wavelength obtained by converting the band gap energy of the active layer 21 is 530 nanometers.

The buffer layer 17, the lower contact layer 18, the lower cladding layer 20, the upper cladding layer 22, and the upper contact layer 23 substantially achieve lattice matching with the substrate 15. The band gap energy and the refractive index of these layers correspond to the values at the intersections of the solid line connecting together the two data points of GaN and InN and the line L2 in FIGS. 2 and 3, respectively. Accordingly, the band gap energy of each of these semiconductor layers is higher than the band gap energy of the active layer 21. Also, the refractive index of each of these semiconductor layers is lower than the refractive index of the active layer 21. As a result, by using these semiconductor layers, it is possible to confine light and carriers in the active layer 21.

Further, the lower contact layer 18 and the lower cladding layer 20 each have the n-type conductivity. In contrast, the upper cladding layer 22 and the upper contact layer 23 each have the p-type conductivity.

Further, a part or all of the growth surface of the buffer layer 17 is a nitrogen polar plane. In contrast, as for the lower contact layer 18, the lower cladding layer 20, the active layer 21, the upper cladding layer 22, and the upper contact layer 23 that are formed on the buffer layer 17, all of each of the growth surfaces thereof is a group-III polar plane.

Further, the lower electrode 19 has, for example, a Ti/Al structure or a Ti/Pt/Au structure. The lower electrode 19 is provided on such a portion of the lower contact layer 18 that is extended on the outer circumferential side of the metapost M, while being formed in the shape of a C when viewed from above.

The current confinement layer 24 is laminated on the upper contact layer 23 and is formed so as to have a ring shape and so as to have an opening 24a that serves as a current injection part. The current confinement layer 24 is electrically insulative and enhances the current density of the electric current injected into the active layer 21 by confining the electric current injected from the upper electrode 26 and causing the electric current to be concentrated within the opening 24a. The current confinement layer 24 is made by using an electrically-insulative material such as Si₃N₄ or SiO₂. Alternatively, it is acceptable to use, as the current confinement layer 24, a layer that is configured so as to have a high level of electric resistance by injecting protons (H+) into a layer including GaInN through an ion injecting process.

The transparent electrically-conductive film 25 is formed so as to cover the current confinement layer 24 and a portion of the upper contact layer 23 exposed in the opening 24a. The transparent electrically-conductive film 25 includes Indium Tin Oxide (ITO), tin oxide doped with antimony oxide or fluorine, or ZnO doped with Al or Ga. The transparent electrically-conductive film 25 has a function of transmitting the light emitted by the active layer 21, and also, of causing the electric current injected from the upper electrode 26 to spread in the width direction (i.e., in-plane direction) so that the electric current is injected into the upper contact layer 23 through the opening 24a of the current confinement layer 24.

The upper electrode 26 has, for example, an Ni/Au structure or a Pd/Pt/Au structure. The upper electrode 26 is provided over the upper contact layer 23 so as to have a ring shape, while the transparent electrically-conductive film 25 is interposed therebetween.

The upper DBR mirror 27 is provided over the upper contact layer 23 so as to cover the opening 24a, while the transparent electrically-conductive film 25 is interposed therebetween. As the upper DBR mirror 27, for example, a mirror that has the same structure as the lower DBR mirror 16 or a structure including a dielectric multi-layer film may be used. The reflectivity of the upper DBR mirror 27 is equal to or higher than 90% and is preferably 99% or higher. It is desirable to configure the reflectivity of the lower DBR mirror 16 and the upper DBR mirror 27 so as to be high, because the threshold current density of the semiconductor light emitting element 400 is reduced when the reflectivity is high.

In the case where a dielectric multi-layer film is used as the upper DBR mirror 27, the dielectric multi-layer film is structured by selecting and combining the materials for the low-refractive-index layers and the high-refractive-index layers as appropriate and laminating as many pairs of low- and high-refractive-index layers as required to realize a desired reflectivity. For example, for the low-refractive-index layers, an oxide dielectric material such as ZrO₂ (2.3), Ta₂O₅ (2.2), HfO₂ (2.11), MgO (1.74), Al₂O₃ (1.7), or SiO₂ (1.5), a nitride dielectric material such as Si₃N₄ (2.0) or AlN (2.1), an oxynitride dielectric material such as SiON (2.0-1.5), or a fluoride dielectric material such as MgF₂ (1.38) may be used. Each of the values in the parentheses indicates the refractive index of the substance.

Further, for the high-refractive-index layers, an oxide dielectric material such as TiO₂ (2.5), Nb₂O₅ (2.4), ZrO₂ (2.3), Ta₂O₅ (2.2), HfO₂ (2.11), MgO (1.74), Al₂O₃ (1.7), or SiO₂ (1.5), a nitride dielectric material such as Si₃N₄ (2.0) or AlN (2.1), an oxynitride dielectric material such as SiON (2.0-1.5), or amorphous silicon such as a-Si:H (4.0) may be used.

Next, an operation performed by the semiconductor light emitting element 400 will be explained. When a voltage is applied between the upper electrode 26 and the lower electrode 19, and also, a driving electric current is injected, electric current is injected into the active layer 21 from the upper electrode 26, while the electric current is concentrated within the opening 24a of the current confinement layer 24 and the density thereof is enhanced. The active layer 21 into which the electric current has been injected generates light including light in the wavelength of 530 nanometers. Due to an optical amplification action of the active layer 21 and an action of the optical resonator structured by the lower DBR mirror 16 and the upper DBR mirror 27, the generated light causes a laser oscillation at the wavelength of 530 nanometers. The laser beam is output upwardly from the upper DBR mirror 27.

In this situation, as described above, the semiconductor light emitting element 400 is configured so that the growth surface of the buffer layer 17 has a nitrogen polar plane, whereas each of the growth surfaces of the lower contact layer 18, the lower cladding layer 20, the active layer 21, the upper cladding layer 22, and the upper contact layer 23 that are formed on the buffer layer 17 has a group-III polar plane. As a result, like the semiconductor light emitting element 100 according to the first embodiment, the semiconductor light emitting element 400 achieves an advantageous effect where the active layer 21 has a sufficient level of photoluminescence intensity. Thus, the semiconductor light emitting element 400 is a laser element having extremely excellent photoluminescence characteristics.

Further, the semiconductor light emitting element 400 is configured so that the buffer layer 17, the lower contact layer 18, and the lower cladding layer 20, as well as the upper cladding layer 22 and the upper contact layer 23 achieve lattice matching with the substrate 15 and so that the lattice constants thereof have values that are close to the lattice constant of the active layer 21. Further, an average lattice constant of the lower DBR mirror 16, which has many layers, matches the lattice constant of the substrate 15, and also, the average lattice constant of the lower DBR mirror 16 is a value close to the lattice constant of the active layer 21. As a result, the impact of strains on the active layer 21 is significantly reduced so that high quality is achieved. Consequently, the semiconductor light emitting element 400 has excellent optical characteristics and higher reliability.

According to the second embodiment, the lower DBR mirror 16 is configured so that the low-refractive-index layers 16a include MgBeO, whereas the high-refractive-index layers 16b include ZnO; however, it is also acceptable to configure a lower DBR mirror by combining ZnMgBeCdO-based materials having other compositions.

It is desirable to configure the composition of the ZnMgBeCdO-based material used for the lower DBR mirror in such a manner that the average lattice constant of the low-refractive-index layers and the high-refractive-index layers is a value within ±3% of the lattice constant of the substrate 15 or the active layer 21, because it is possible to inhibit the impact of the strains. Further, it is also desirable to configure the composition of the lower DBR mirror in such a manner that the band gap energy thereof is higher than the band gap energy of the active layer 21, because, in that situation, the lower DBR mirror does not absorb the light from the active layer 21 and there is no possibility that the threshold value of the laser oscillation may increase or that the intensity of the laser beam may becomes lower.

Next, a method of manufacturing the semiconductor light emitting element 400 according to the second embodiment will be explained. First, the substrate 15 that is made by using a ZnO single crystal is prepared, and Steps 1 and 2 that are the same as those in the first embodiment described above are performed.

Subsequently, while using the substrate 15 as a growth substrate, a desired number of pairs made up of the low-refractive-index layers 16a and the high-refractive-index layers 16b that are adjusted so as to have desired compositions are epitaxially grown on the substrate 15, so as to form the lower DBR mirror 16. The process to form the lower DBR mirror 16 may be performed by using a Pulse Laser Deposition (PLD) method, an MBE method, a Metal-Organic Chemical Vapor Deposition (MOCVD) method, or the like.

When the PLD method or the MBE method is used, it is possible to use, as an oxygen source, an oxygen plasma cell that is configured so as to generate oxygen radicals. It is possible to supply Zn, Mg, Be, and Cd as metal raw materials by using Knudsen cells.

By using the MOCVD method, it is possible to form the lower DBR mirror 16 by supplying, as raw materials, organic metal materials such as a raw material for Zn being a group II material like diethylzinc (DEZn) or dimethylzinc (DMZn), a raw material for Mg like diethylmagnesium (DEMg) or dimethylmagnesium (DMMg), a raw material for Cd like diethylcadmium (DECd) or dimethylcadmium (DMCd), a raw material for Be like diethylberyllium (DEBe) or dimethylberyllium (DMBe), as well as oxygen (O₂) serving as a raw material for O.

After that, by performing the same processes as at Steps 3 through 6 in the first embodiment, the buffer layer 17 of which the growth surface has a nitrogen polar plane as well as the lower contact layer 18, the lower cladding layer 20, the active layer 21, the upper cladding layer 22, and the upper contact layer 23 of which the growth surfaces each have a group-III polar plane are grown so as to manufacture an epitaxial wafer to be used for the semiconductor light emitting element 400 according to the second embodiment.

Formation of a Surface Emitting Laser Structure

Next, a procedure for forming a surface emitting laser structure of the semiconductor light emitting element 400 by using the epitaxial wafer that has been manufactured as described above will be explained.

First, a metapost M is formed. More specifically, a circular mask pattern corresponding to the outer circumference of the upper electrode 26 is formed by performing a photolithography process. By using the formed mask pattern as a mask, a wet etching process or a dry etching process is applied to the regions from the upper contact layer 23 up to the top of the lower contact layer 18, so as to form the metapost M.

Subsequently, the lower electrode 19 is formed. First, a mask that has a pattern corresponding to the shape of the lower electrode 19 is formed. After an electrode metal having a Ti/Al structure or a Ti/Pt/Au structure has been deposited by using a resistance heating evaporation method, an electron beam deposition method, or a sputter deposition method, a lift-off process and a sintering process are performed so as to form the lower electrode 19. The lower electrode 19 that has been formed is in ohmic contact with the lower contact layer 18, which has the n-type conductivity.

After that, the current confinement layer 24 is formed. More specifically, an SiO₂ layer or an Si₃N₄ layer is deposited on the upper contact layer 23 by performing a sputtering process or by using a PCVD method, and the current confinement layer 24 is formed by performing a photolithography process.

After that, the transparent electrically-conductive film 25 is formed by depositing, for example, an ITO film on the entire surface. Further, the upper electrode 26 having an Ni/Au structure or a Pd/Pt/Au structure is formed on the transparent electrically-conductive film 25 so as to surround the opening 24a of the current confinement layer 24. Subsequently, the upper DBR mirror 27 is formed on the inside of the upper electrode 26 by performing a sputtering process or by using a PCVD method. After that, the element is separated by performing a dicing process. As a result, the semiconductor light emitting element 400 according to the second embodiment, which is a surface emitting laser element, has thus been completed.

During the dicing process, it is also acceptable to cut out a plurality of surface emitting laser elements that are arranged in a one-dimensional formation or a two-dimensional formation so as to obtain surface emitting laser array elements. Further, in the case where these elements are to be installed into a can package such as a Transistor Outline Can (TO-Can), the following procedure, for example, may be performed: First, an element that has been cut out is bonded onto a heat sink or a submount and is further bonded onto a heat sink that is made of copper or the like. After that, the structure obtained by bonding the element is placed on the can, and the electrode part of the element is wire-bonded with the can. After that, the can is finally sealed in a vacuum, in nitrogen atmosphere, or the like. The installation of the element with the can has thus been completed.

Further, in the exemplary embodiments described above, the nitride semiconductor layers including the active layer are grown by using the nitrogen RF radical source MBE method; however, it is also acceptable to use other MBE methods such as a gas source MBE, a PLD method, or a MOCVD method.

When the PLD method or the MBE method is used, it is possible to use, as a nitrogen source, a nitrogen plasma cell that is configured so as to generate nitrogen radicals. It is possible to supply Al, Ga, and In as raw materials for group-III, by using Knudsen cells.

By using the MOCVD method, it is possible to use ammonia (NH₃) as a nitrogen source. Also, the nitride semiconductor layers are grown by supplying, as raw materials for group-III, a raw material for Al like trimethylaluminum (TMA) or triethylaluminum (TEA), a raw material for Ga like trimethylgallium (TMG) or triethylgallium (TEG), and a raw material for In like trimethylindium (TMI) or triethylindium (TEI), as appropriate.

To form the buffer layer 17 on the lower DBR mirror 16 that includes an oxide semiconductor, it is preferable to use the MBE method or the like, because ammonia and an oxide semiconductor react with each other at a relatively low temperature, and the oxide semiconductor sublimes. Further, after an interface between the oxide semiconductor and the nitride semiconductor has been formed by the above preferable method, it is possible to obtain the nitride semiconductor layers having a better crystal quality by using the MOCVD method. In addition, there is a possibility that the lateral faces and the rear surfaces of the substrate 15 and the lower DBR mirror 16 that include oxide semiconductors may sublime due to a reaction with ammonia, while the nitride semiconductor layers are grown by using the MOCVD method. Thus, it is desirable to protect the lateral faces and the rear surfaces by using an electrically-insulative film like Si₃N₄ or SiO₂, metal, or the like.

Further, according to the exemplary embodiments described above, each of the growth surfaces of the nitride semiconductor layers other than the buffer layer has a group-III polar plane; however, as long as at least the growth surface of the active layer has a group-III polar plane, it is possible to achieve the advantageous effect of the present invention where the photoluminescence characteristics are excellent. Further, as described in the exemplary embodiments above, it is possible to achieve the advantageous effect of the present invention when the entirety of the growth surface of the buffer layer is a nitrogen polar plane, while the entirety of the growth surface of the active layer is a group-III polar plane, or when at least a part of the growth surface of the buffer layer is a nitrogen polar plane.

Further, according to the exemplary embodiments described above, the substrate including ZnO is used as the supporting substrate; however, the present invention is not limited to this example. For example, another arrangement is acceptable in which, after the semiconductor layers have been grown while using a substrate including ZnO as a growth substrate, the growth substrate and the semiconductor layered structure are separated from each other, then the semiconductor layered structure is mounted onto, for example, a supporting substrate (e.g., an Si substrate) that has an even higher heat conductivity than a ZnO substrate or onto a heat sink. By using a supporting substrate that has an even higher heat conductivity in this manner, it is possible to obtain a semiconductor light emitting element that has excellent optical characteristics and reliability and that is also suitable for the use under a higher-temperature environment. Alternatively, instead of separating the growth substrate, another arrangement is acceptable in which a part of the growth substrate is removed by a polishing process such as CMP so that the thickness becomes smaller, before the semiconductor layered structure is mounted onto another supporting substrate or the like having a higher heat conductivity.

The process to separate the growth substrate and the semiconductor layered structure from each other may be performed by using a publicly-known laser lift-off technique. Alternatively, it is also acceptable to perform the separation process by entirely removing the growth substrate from the semiconductor layered structure by performing a polishing process such as CMP. Further, it is also acceptable to entirely remove the growth substrate by performing a wet etching process. Further, it is preferable to form thick semiconductor layers by using a Hydride Vapor Phase Epitaxy (HVPE) method to grow the nitride semiconductor layers because it is easy to separate the growth substrate or to partially or entirely remove the growth substrate by performing a polishing process. It is possible to separate the growth substrate or to partially or entirely remove the growth substrate by performing a polishing process, either before or after the element is manufactured in the manner described above.

According to the exemplary embodiments described above, the semiconductor light emitting element is a laser element; however, the semiconductor light emitting element according to the present invention is not limited to a laser element. For example, the semiconductor light emitting element may be a Light Emitting Diode (LED).

Further, according to the exemplary embodiments described above, the active layer has a bulk structure; however, the active layer may have a single or multi quantum well structure. Further, it is acceptable to form an optical confinement layer or a carrier confinement layer between the active layer and the lower cladding layer and/or between the active layer and the upper cladding layer, to realize a Separate Confinement Heterostructure (SCH) that is provided with an optical guiding layer.

Further, in any of the exemplary embodiments described above, it is acceptable to provide a carrier (electron) blocking layer between the active layer and a p-type optical guiding layer or a p-type cladding layer.

Furthermore, according to the exemplary embodiments described above, each of the semiconductor layers positioned below the active layer has the n-type conductivity, whereas each of the semiconductor layers positioned above the active layer has the p-type conductivity; however, each of the semiconductor layers positioned on the lower side may have the p-type conductivity.

Further, it is acceptable to epitaxially grow a ZnO layer having the n-type conductivity or the p-type conductivity on a substrate and to use the ZnO layer as a base layer for the buffer layer or for the lower DBR mirror.

Furthermore, according to the exemplary embodiments described above, the lower DBR mirror is made by using a ZnMgBeCdO-based material; however, it is acceptable to use an AlGaInN-based material. In that situation, it is desirable to insert a buffer layer including AlGaInN that a nitrogen polar plane, between the lower DBR mirror and the growth substrate including ZnO.

In addition, by appropriately selecting the composition of the AlGaInN-based material and the thickness of the active layer, it is possible to realize a semiconductor light emitting element that has a desired photoluminescence wavelength or a desired laser oscillation wavelength having a wide range from the ultraviolet region to the visible region.

As explained above, the semiconductor light emitting element and the method of manufacturing thereof according to some aspects of the present invention are suitable for realizing various types of semiconductor light emitting elements that have excellent photoluminescence characteristics.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A semiconductor light emitting element comprising:
a buffer layer that is grown by using a growth substrate including ZnO, the buffer layer being made by using an AlGaInN-based material including In and being configured so that a growth surface thereof has a nitrogen polar plane; and
an active layer that is formed on the buffer layer, the active layer being made by using an AlGaInN-based material including In and being configured so that a growth surface thereof has a group-III polar plane.

2. The semiconductor light emitting element according to claim 1, wherein a plane orientation of a main surface of the growth substrate corresponds to a c-plane.

3. The semiconductor light emitting element according to claim 1, wherein a main surface of the growth substrate is a vicinal plane that is slightly inclined with respect to a c-plane.

4. The semiconductor light emitting element according to claim 2, wherein the main surface of the growth substrate is an oxygen polar plane.

5. The semiconductor light emitting element according to claim 3, wherein the main surface of the growth substrate is an oxygen polar plane.

6. The semiconductor light emitting element according to claim 1, wherein the semiconductor light emitting element is a laser element of an edge emitting type.

7. The semiconductor light emitting element according to claim 1, wherein the semiconductor light emitting element is a light emitting diode.

8. The semiconductor light emitting element according to claim 1, wherein
the buffer layer is grown directly on a multi-layer reflective mirror that is grown by using the growth substrate and that includes such a structure in which low-refractive-index layers and high-refractive-index layers each of which is made by using a ZnMgBeCdO-based material are alternately laminated, and
the semiconductor light emitting element is a surface emitting laser element.

9. The semiconductor light emitting element according to claim 1, comprising the growth substrate as a supporting substrate.

10. A method of manufacturing a semiconductor light emitting element comprising:
growing a buffer layer on a growth substrate including ZnO, the buffer layer being made by using an AlGaInN-based material including In and being configured so that a growth surface thereof has a nitrogen polar plane; and
growing an active layer on the buffer layer, the active layer being made by using an AlGaInN-based material including In and being configured so that a growth surface thereof has a group-III polar plane.

11. The method of manufacturing a semiconductor light emitting element according to claim 10, wherein the active layer is grown at a temperature that is higher than a growth temperature of the buffer layer.

12. The method of manufacturing a semiconductor light emitting element according to claim 11, wherein the buffer layer is grown at a temperature that is lower than 500° C., whereas the active layer is grown at a temperature that is higher than 500° C.

13. The method of manufacturing a semiconductor light emitting element according to claim 11, wherein the buffer layer and the active layer are grown by supplying nitrogen radicals and a group III element and the supply of the group III element and the nitrogen radicals is temporarily stopped while the growth temperature for the buffer layer is raised to the growth temperature for the active layer.

14. The method of manufacturing a semiconductor light emitting element according to claim 10, wherein the buffer layer is grown by supplying nitrogen radicals at a beginning, and subsequently, supplying a group III element.

15. The method of manufacturing a semiconductor light emitting element according to claim 10, wherein the active layer is grown by supplying a group III element at a beginning, and subsequently, supplying nitrogen radicals.

16. The method of manufacturing a semiconductor light emitting element according to claim 10, wherein the buffer layer is grown by supplying nitrogen radicals and a group III element in such a manner that a ratio of the nitrogen radicals to the group III element is higher than 1:1.

17. The method of manufacturing a semiconductor light emitting element according to claim 10, wherein the active layer is grown by supplying nitrogen radicals and a group III element in such a manner that a ratio of the group III element to the nitrogen radicals is higher than 1:1.
